(19) United States
(12) Patent Application Publication
(10) Pub. No.: US 2013/0313582 A1
(43) Pub. Date: Nov. 28, 2013

(54) UNITARY DISPLAY PANNEL AND METHOD OF MANUFACTURING THE SAME

(71) Applicant: SAMSUNG DISPLAY CO., LTD., Yeongin-City (KR)

(72) Inventors: Young-Joon CHO, Suwon-si (KR); Joon-Chul GOH, Hwaseong-si (KR); Yeun-Tae KIM, Suwon-si (KR); Nak-Cho CHOI, Hwaseong-si (KR)

(73) Assignee: SAMSUNG DISPLAY CO., LTD., YEONGIN-CITY (KR)

(21) Appl. No.: 13/668,015

(22) Filed: Nov. 2, 2012

(30) Foreign Application Priority Data
May 23, 2012 (KR) 10-2012-0055009

(51) Int. Cl. H01L 33/08

(52) U.S. Cl. 257/88; 438/34; 257/E33.053

(57) ABSTRACT

A monolithically integrated display panel is formed to include a substrate, a first electrode disposed on the substrate, a partitioning member disposed above the first electrode where the partitioning member defines a substantially containerizing volume for a to-be-introduced and then later selectively removed sacrificial member, a light attribute controlling material disposed in the containerizing volume and replacing the selectively removed sacrificial member, where an upper width of the light attribute controlling material is substantially different in dimension than a lower width of the light attribute controlling material, and a second electrode disposed above the light attribute controlling material and insulated from the first electrode.

### CROSS-REFERENCE TO RELATED APPLICATION

This application claims priority under 35 U.S.C. §119 to Korean Patent Application No. 10-2012-0055009, filed on May 23, 2012, in the Korean Intellectual Property Office (KIPO), the contents of which application are incorporated by reference herein in their entireties.

### BACKGROUND

1. Field of Disclosure

The present disclosure of invention relates to a display panel and to a method of the display panel.

More particularly, the present disclosure relates to a unitary display panel that has a tunnel-shaped cavity defined therein for receiving a liquid and a method of manufacturing the display panel.

2. Discussion of Related Technology

Recently, liquid crystal or other liquid-containing display apparatuses have come into vogue due to the ability to manufacture the same with light weight and small size. In earlier times, a cathode ray tube (CRT) display apparatus was used due to performance and competitive price considerations. However the CRT display apparatus has a weakness with a size and portability. Therefore the liquid display apparatus (e.g., LCD) has been highly regarded due to small size, light weight and low-power-consumption of the liquid display apparatus.

Generally, the liquid display apparatus applies an electric field (e.g., a voltage) to a liquid molecular arrangement where the field is configured to change the molecular arrangement. The liquid display apparatus displays an image using changes of one or more optical properties (for example, birefringence, rotatory polarization, dichroism and light scattering) of a liquid (e.g., liquid crystal) within the liquid-containing display where the optical changes correspond to the electric field induced changes of the molecular arrangement.

In some embodiments, the liquid display apparatus includes alignment layer on a surface of each liquid-containing cell for causing the contained liquid (e.g., liquid crystal molecules) to initially become aligned in a specific direction even when no field is applied. In some embodiments, a problem arises when the liquid molecules in a peripheral portion of the liquid-containing cell are uncontrolled by an alignment layer and thus they may become aligned in an unintended direction.

It is to be understood that this background of the technology section is intended to provide useful background for understanding the here disclosed technology and as such, the technology background section may include ideas, concepts or recognitions that were not part of what was known or appreciated by those skilled in the pertinent art prior to corresponding invention dates of subject matter disclosed herein.

### SUMMARY

The present disclosure of invention provides a monolithically integrated display panel that is formed as a unitary structure rather than as separate pieces that are glued or otherwise fastened to one another.

The present disclosure of invention also provides a method of manufacturing the unitary display panel.

According to an example embodiment, a unitary display panel includes a substrate, a first electrode disposed on the substrate, a partitioning member disposed above the first electrode, the partitioning member having an opening for substantially containerizing a to-be-introduced and later selectively removed sacrificial member, a light attribute controlling material (e.g., a liquid crystal layer) disposed in the opening of the partitioning member (after the sacrificial member has been removed), where an upper width of the light attribute controlling material is different in dimension than a lower width of the light attribute controlling material, and a second electrode disposed above the light attribute controlling material and insulated from the first electrode.

In an example embodiment, the display panel may further include a lower insulation layer disposed between the first electrode and the light attribute controlling material.

In an example embodiment, the display panel may further include an upper insulation layer disposed between the light attribute controlling material and the second electrode.

In an example embodiment, the upper and lower insulation layers include respective inorganic insulating materials while the selectively removable sacrificial member includes an organic material which is selectively removable relative to the inorganic insulating materials of the upper and lower insulation layers.

In an example embodiment, the display panel may further include a third insulation layer disposed between the first insulation layer and the first electrode. The third insulation may be disposed under the partitioning member.

In an example embodiment, the display panel may further include a thin film transistor disposed on the substrate and comprising a gate electrode, a source electrode and a drain electrode, and a storage electrode forming a capacitor with the drain electrode, a source electrode and a drain electrode.

In an example embodiment, the display panel may further include a black matrix disposed over the thin film transistor and configured to block light.

In an example embodiment, the storage electrode may include a storage electrode branch forming a capacitor with the first electrode.

In an example embodiment, the second electrode may have an opening overlapping with the storage electrode branch.

In an example embodiment, at least one of the first and second electrodes may have one or more openings overlapping with the storage electrode branch.

In an example embodiment, the display panel may further include a color filter disposed on the second electrode.

In an example embodiment, the display panel may further include a fourth insulation layer disposed on the color filter, and a protecting layer disposed on the fourth insulation layer.

In an example embodiment, the display panel may further include an alignment layer surrounding the light attribute controlling material (e.g., the liquid crystal).

According to another example embodiment, a method of forming a unitary display panel includes forming a first electrode on a substrate, forming a partitioning member that substantially defines a containerizing volume overlapping the first electrode in a plan view, forming a sacrificial layer in the containerizing volume and overlapping the first electrode, forming a second electrode above the sacrificial layer, creating a tunnel-shaped cavity by selectively removing the sacrificial layer, the tunnel-shaped cavity being disposed between the first electrode and the second electrode, and flowing a light attribute controlling material or a liquid precursor of the light attribute controlling material into the tunnel-shaped cavity.

In an example embodiment, the method may further include forming a lower insulation layer on the first electrode but before forming the sacrificial layer, and forming an upper insulation layer above the sacrificial layer but before forming the second electrode.

In an example embodiment, the sacrificial member may include an organic material that is selectively removable for example by means of an anisotropic microwave O2 plasma process.

In an example embodiment, forming the light attribute controlling material may include causing an upper width of the light attribute controlling material to be wider than a lower width of the light attribute controlling material.

In an example embodiment, forming the tunnel-shaped cavity may include forming a hole through the second electrode to access the sacrificial member for removal of the sacrificial member.

In an example embodiment, forming display layer may include forming an alignment layer on at least one interior surface of the tunnel-shaped cavity before the light attribute controlling material (or a liquid precursor thereof) is filled into the tunnel-shaped cavity in which the alignment layer is already formed.

According to still another example embodiment, a display panel includes a substrate, a first electrode disposed on the substrate, a partitioning member disposed on the substrate on which the first electrode is disposed and having an opening, a light attribute controlling material (e.g., liquid crystal layer) disposed in the opening, where an upper width of the light attribute controlling material is substantially smaller than a lower width of the light attribute controlling material, a second electrode disposed above the light attribute controlling material, and insulated from the first electrode, a thin film transistor disposed on the substrate and comprising a gate electrode, a source electrode and a drain electrode, and a storage electrode forming a capacitor with the drain electrode and having a storage electrode branch forming a capacitor with the first electrode. An upper width of a partition wall defined by the partitioning member is greater than a lower width of the partition wall, and at least one of the first and second electrodes has openings overlapping with the storage electrode branch.

According to the present disclosure of invention, the light attribute controlling material is injected into the tunnel-shaped cavity of the monolithically integrally formed structure, so that a number of individual substrates used for manufacturing for the display apparatus may be reduced.

In addition, texture in a peripheral area of the light attribute controlling material (e.g., liquid crystal layer) may be controlled by adjusting a slant angle of a sidewall of the partitioning member.

In addition, the angle of a sidewall of the liquid crystal layer may be controlled by adjusting the selective removal of the sacrificial layer.

### BRIEF DESCRIPTION OF THE DRAWINGS

The above and other features of the present disclosure of invention will become more apparent by describing in detail example embodiments thereof with reference to the accompanying drawings, in which:

FIG. 1 is a top plan view illustrating a display apparatus layout according to an example embodiment;

FIG. 2A is cross-sectional view taken along a line I-I′ of FIG. 1;

FIG. 2B is cross-sectional view taken along a line II-II′ of FIG. 1;

FIG. 2C is cross-sectional view taken along a line III-III′ of FIG. 1;

FIGS. 3A to 3F are cross-sectional views illustrating a method of manufacturing a display panel according to an example embodiment of the present disclosure of invention;

FIG. 4A is a cross-sectional view, which is correspond to the line I-I′ of FIG. 1, of a display apparatus according to another example embodiment;

FIG. 4B is a cross-sectional view, which is correspond to the line II-II′ of FIG. 1, of the display apparatus of FIG. 4A;

FIG. 5 is a plan view illustrating a display apparatus according to still another example embodiment;

FIG. 6 is cross-sectional view taken along a line I-I′ of FIG. 5;

FIG. 7 is a flowchart illustrating a method of manufacturing a display panel according to an example embodiment; and

FIG. 8 is a flowchart illustrating forming liquid crystal layer of FIG. 7.

### DETAILED DESCRIPTION

Hereinafter, the present disclosure of invention will be explained in detail with reference to the accompanying drawings.

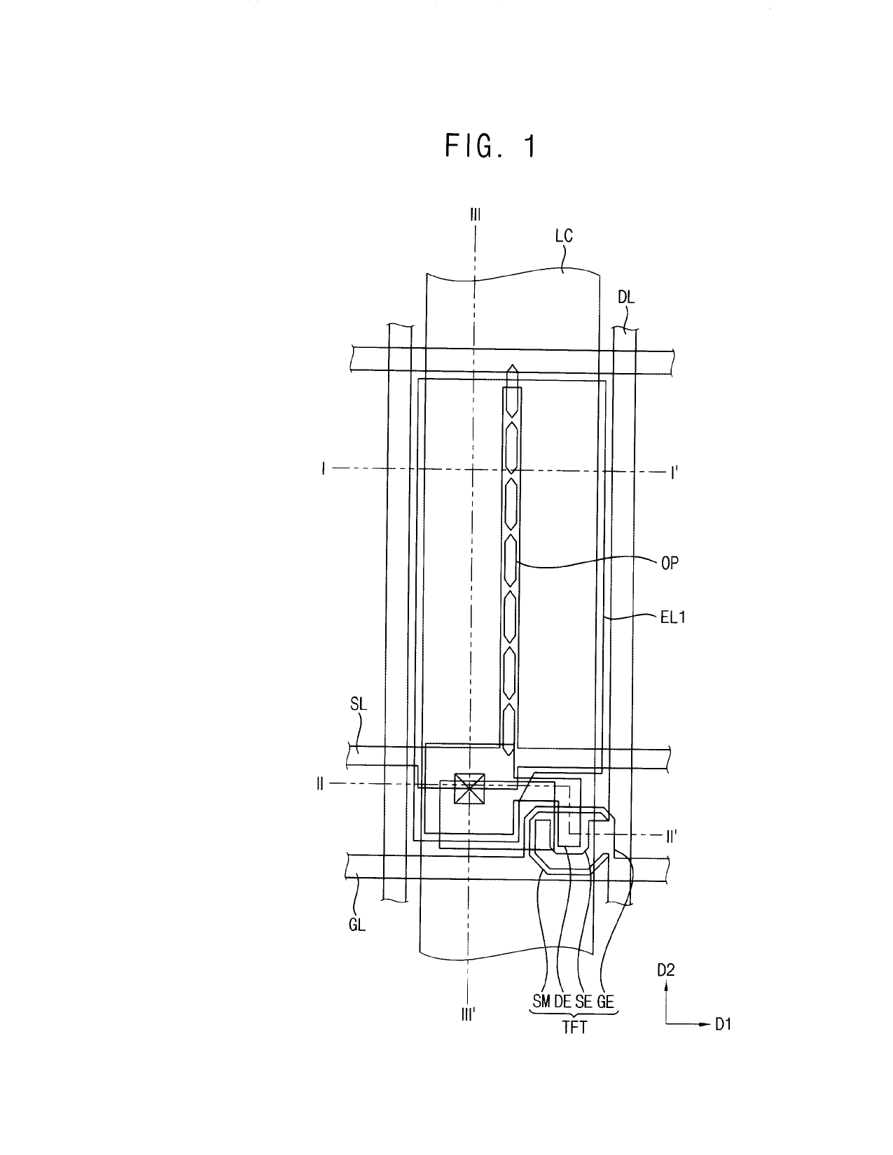

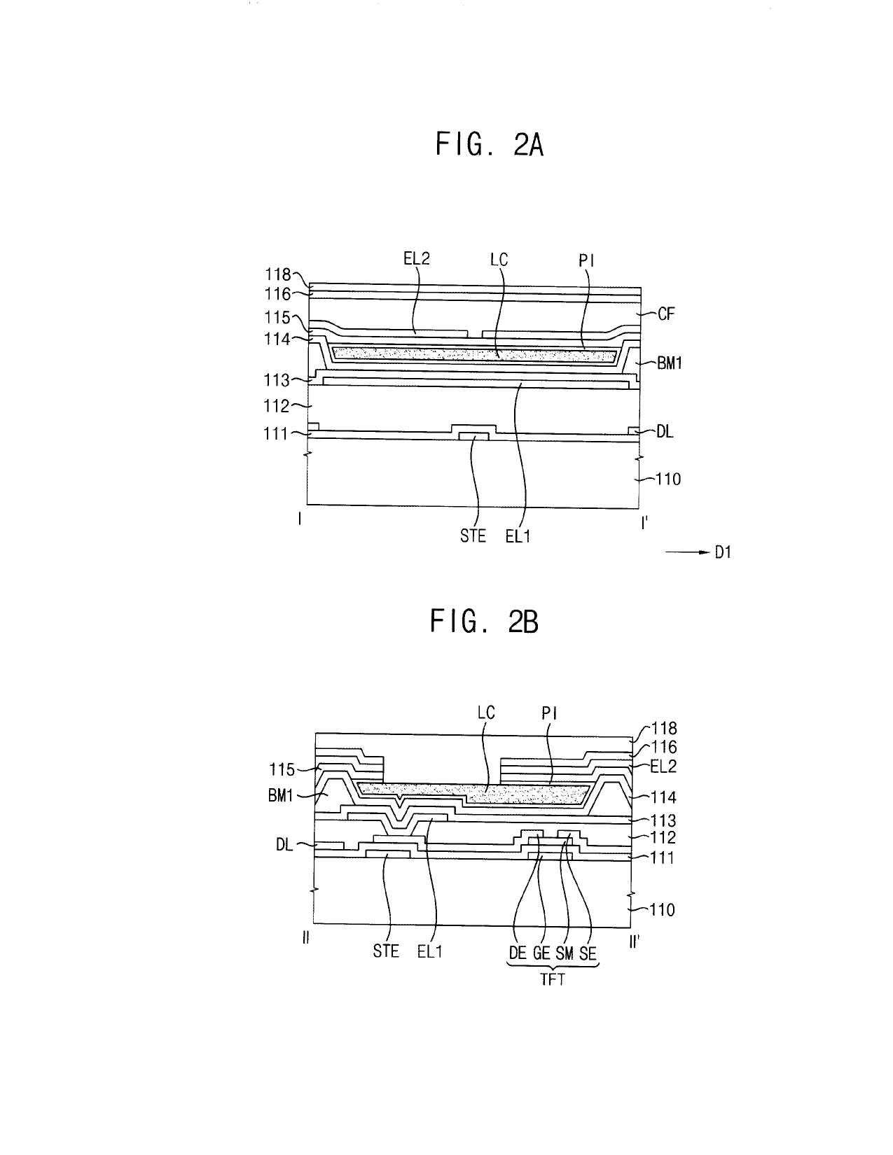

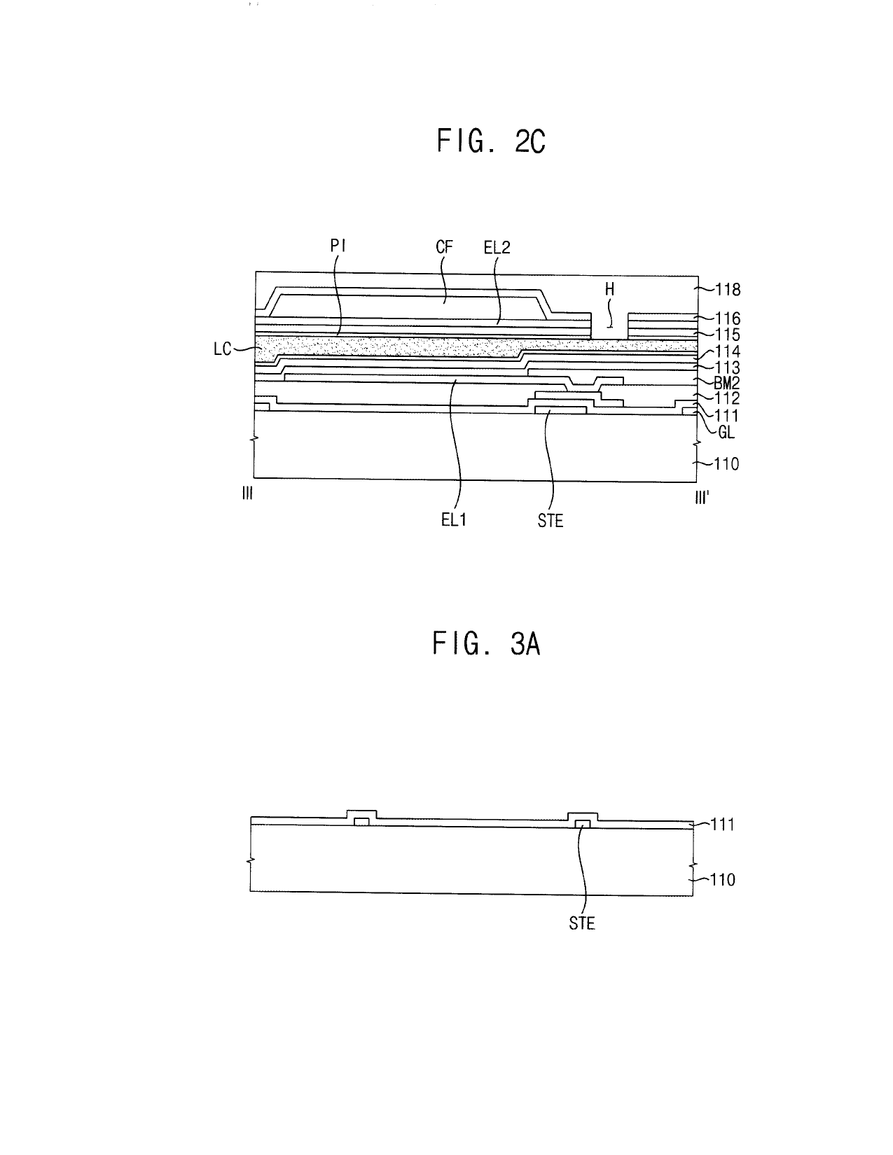

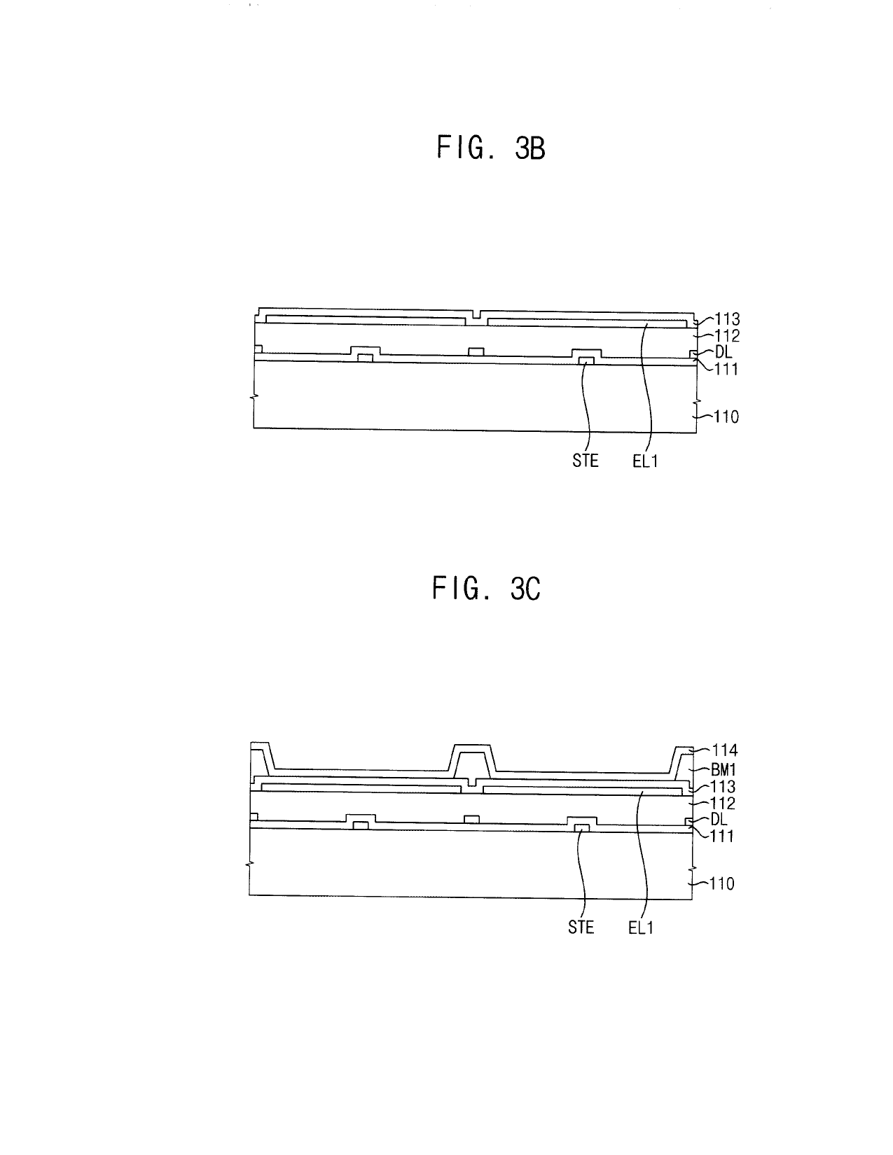

FIG. 1 is a top plan view (and an approximately to scale view) illustrating a layout of a display apparatus according to a first example embodiment. FIG. 2A is a possible cross-sectional view taken along a line I-I′ of FIG. 1. FIG. 2B is a possible cross-sectional view taken along a line II-II′ of FIG. 1. FIG. 2C is a possible cross-sectional view taken along a line III-III′ of FIG. 1.

Referring to FIGS. 1 to 2C, the display panel embodiment of these figures taken in combination includes a substrate 110, a thin film transistor TFT, a first electrode EL1, a second electrode EL2 (split into two domains by openings OP), a liquid-containing volume which in the instant example contains a liquid crystal LC and a first black matrix BM1. The display panel further includes a first insulation layer 111, a second insulation layer 112, a third insulation layer 113, a fourth insulation layer 114, a fifth insulation layer 115, a color filter CF and a sixth insulation layer 116. More specifically, in one embodiment, the various layers of the display panel are monolithically integrated (for example by automated fabrication equipment) as one unitary structure rather than being hand assembled (e.g., glued together) from two or more pre-assembled other structures (e.g., a separate common electrode substrate and a separate transistor array substrate).

The base substrate 110 may be a transparent insulation substrate made for example of glass and/or plastic. The substrate 110 is subdivided into a plurality of pixel areas PA's. Although only one pixel area PA is generally described in the figures, the display panel according to the example embodiments generally includes a large number of pixel units respectively formed in respective pixel areas PA's. The pixel areas PA's are typically arrayed for example as a regular matrix structure having a plurality of rows and columns. The pixel areas PA's typically have same basic and repeated structures (although some variation for example in color of color filter portion or size or shape of pixel-electrode may occur), so that only one pixel area PA will be described herein as an example. Although the pixel area PA has a rectangular shape in the figures, the pixel area PA may have various modifications in size and/or shape and/or number of field altering slits or other fine features included therein. For example the pixel areas PA may have V or Z shapes.

A gate line GL is monolithically integrally disposed on the substrate 110 and extends in a first direction D1.

A storage line SL is monolithically integrally disposed on the substrate 110 and also extend in the first direction D1. The storage line SL is spaced apart form the gate line GL.

A storage electrode STE is integrally branched out from the storage line SL. The storage electrode STE extends in a second direction D2 which is substantially perpendicular to the first direction D1, so that the storage electrode STE forms a branch. The branch of the storage electrode STE forms a capacitor with the first electrode EL1 A portion of the storage electrode STE extends in a direction opposite to the main branch with respect to the storage line SL. That portion of storage electrode STE forms a capacitor with a drain electrode DE of the thin film transistor TFT.

A gate electrode GE of the thin film transistor TFT is disposed on the substrate 110 and integrally connected to (branched from) the gate line GL.

The first insulation layer 111 is monolithically integrally formed on the gate line GL, the gate electrode GE of the thin film transistor TFT and the storage line SL.

A semiconductor pattern SM of the thin film transistor TFT is monolithically integrally disposed on the first insulation layer 111, and overlaps with the gate electrode GE.

A data line DL is monolithically integrally disposed on the first insulation layer 111, and extends in the second direction D2. A source electrode SE of the thin film transistor TFT is similarly disposed on the semiconductor pattern SM, and connected to the data line DL. (To avoid yet further repetition of the term, “monolithically integrally”, the same will be understood as implied for other structural features that are formed one over the next to create the here described panel unless otherwise stated.

The drain electrode DE of the thin film transistor TFT is disposed on the semiconductor pattern SM and the first insulation layer 111. A portion of the drain electrode DE overlaps with the portion of the storage electrode STE.

The thin film transistor TFT includes the gate electrode GE, the source electrode SE, the drain electrode DE and the semiconductor pattern SM.

The drain electrode DE is spaced apart from the source electrode SE on the semiconductor pattern SM. The semiconductor pattern SM defines a channel region between the source electrode SE and the drain electrode DE. An electric field applied to the gate electrode GE can control the conductivity of the channel region.

The second insulation layer 112 is disposed on the thin film transistor TFT and the data line DL. A contact hole is formed to partially overlap the storage electrode STE and the drain electrode DE through the second insulation layer 112. Thus, the contact hole exposes a portion of the drain electrode DE.

The first electrode EL1 (e.g., one made of an electrically conductive and optically transparent material such as ITO, IZO, etc.) is disposed on the second insulation layer 112. The first electrode EL1 is deposited so as to become integrally connected to the drain electrode DE through the contact hole. The first electrode EL1 covers most of the pixel area PA (see FIG. 1). Although the first electrode EL1 has a rectangular shape in the present example embodiment, the first electrode EL1 may have various modifications of shape and size. The first electrode EL1 may be partially eliminated by, for example, patterning the first electrode EL1 to have a plurality of stems and branches from the stems for creating differentiated electric fields (different liquid crystal orientation domains).

The third insulation layer 113 is disposed on the first electrode EL1.

The first black matrix BM1 is disposed on the third insulation layer 113. The first black matrix BM1 overlaps the data line DL and extends in the second direction D2.

In one embodiment, sidewalls of a cross section of the first black matrix BM1 and a major under surface of the first black matrix BM1 which faces the third insulation layer 113, form a predetermined angle other than 90 degrees (e.g., less than 90 degrees). Thus, a lower width of the cross section of the first black matrix BM1 may be greater than an upper width of the first black matrix BM1 and in FIGS. 2A-2B the cross section appears substantially as a trapezoidal shape with a wider base and a narrower top side.

A lower portion of the first black matrix BM1 cross section may block leakage light from undesirably bypassing an edge portion of the liquid crystal layer LC without being controlled by the liquid crystal layer LC. Since the lower width of the cross section (e.g., trapezoidal cross section) of the first black matrix BM1 is greater than the upper width of the same, the degree of light blocking provided thereby may be controlled (e.g., fine tuned) by selectively adjusting the lower width of the cross section of the first black matrix BM1. Thus, by fine tuning the lower width to minimize the amount of leaked light, an aperture ratio of the pixel area may be improved. For example, in a PA mode display apparatus, light leakage due to the unintended misalignment of liquid crystal molecules in an edge of the liquid crystal layer LC may be decreased.

The first black matrix BM1 may alone or with other features (e.g., 114) define a unitary partitioning member having openings in a plan view where the openings define the aforementioned slanted sidewalls of the cross sections (e.g., trapezoidal ones) of the first black matrix BM1 (and of the fourth insulation layer 114).

A second black matrix BM2 (FIG. 2C) is disposed between the second insulation layer 112 and the third insulation layer 113, and overlaps with the thin film transistor TFT.

The first and second black matrix BM1 and BM2 block light which is unnecessary to display a liquid-controlled image. For example, the first and second black matrix BM1 and BM2 prevent form light leakage in an edge of a display area, and color mixture in an edge of the color filter CF.

The fourth insulation layer 114 is disposed on the first black matrix BM1 and the third insulation layer 113.

The liquid crystal layer LC is disposed above the fourth insulation layer 114. The slanted sidewalls of the first black matrix BM1 help to define a trapezoidal wall shape that first compartmentalizes (e.g., partially containerizes) an initially introduced there-into sacrificial material and later compartmentalizes the liquid crystal layer LC that replaces the sacrificial material. Thus, an upper width of the so-compartmentalized liquid crystal layer LC is greater than a lower width of the liquid crystal layer LC due to the slanting of the sidewalls of the openings formed through the first black matrix BM1 as may be seen for example in FIGS. 2A and 2B.

The fifth insulation layer 115 is disposed over the volume that containerizes the liquid crystal layer LC and over the fourth insulation layer 114.

An alignment layer PI may be disposed on an interior surface of the liquid-containing volume, for example between the fourth insulation layer 114 and the liquid crystal layer LC, and also between the fifth insulation layer 115 and the liquid crystal layer LC. The alignment layer PI pre-tilts the liquid crystal molecules in the liquid crystal layer LC. However the alignment layer PI may be optionally eliminated according to a type of the liquid crystal layer LC or a structure of the first and second electrodes EL1 and EL2. For example, if the first electrode EL1 has one or more micro silts, the liquid crystal layer LC may be aligned without an additional alignment layer, and then the alignment layer PI may be eliminated. In addition, when the display panel includes a reactive-mesogen layer for initial alignment of the liquid crystal layer LC, then the alignment layer PI may be eliminated.

The second electrode EL2 is dispose on the fifth insulation layer 115. A voltage placed across the second electrode EL2 and the first electrode EL1 forms an electric field between the first electrode EL1 and the second electrode EL2. A portion of the second electrode EL2 is spaced apart from the fourth insulation layer 114, so that a tunnel-shaped cavity is integrally formed between the fourth insulation layer 114 and the second electrode EL2. Although the liquid crystal layer LC is disposed in the tunnel-shaped cavity in the present example embodiment, another type of, at least initially, liquified image display material may be flowed into the tunnel-shaped cavity and optionally solidified or otherwise modified thereafter to form an electrically controlled layer for displaying an image. For example, an electrophoresis layer having charged microcapsules suspended in a suspension liquid may be disposed in the tunnel-shaped cavity.

The liquid crystal layer LC includes liquid crystal molecules having optical anisotropy. The liquid crystal molecules are driven by a generated electric field, so that a desired image is displayed by selectively passing or blocking different amounts of light as a result of optical orientation applied to the liquid crystal layer LC.

When the electrophoresis layer is disposed in the tunnel-shaped cavity, the electrophoresis layer includes insulative medium and charge carriers. The insulative medium is a dispersion medium of the dispersed charge carriers (e.g., microcapsules). The charge carriers have electrophoresis properties and are diffused in the insulative medium. The charge carriers are moved (e.g., rotated) to align with the direction of the electric field, so that an image may be displayed by for example selectively passing or blocking different amounts of light through the electrophoresis layer and/or reflecting different amounts of, or different colors of light from the electrophoresis layer.

The second electrode EL2 has one or more openings OP. The opening(s) OP overlaps with the branch of the storage electrode STE which is overlapped with the first electrode EL1 The opening OP forms a slit pattern on the second electrode EL2 thereby defining split domains.

The opening OP overlaps with the branch of the storage electrode STE. Thus, the branch of the storage electrode STE may block leakage light from passing through the opening OP where the orientation of liquid crystal molecules may be less well controlled due to the opening(s) OP being present there.

The color filter CF is integrally disposed on the second electrode EL2. The color filter CF supplies coloring effects to the passing therethrough light. The color filter CF may include a red color filter, a green color filter and blue color filter. The color filter CF corresponds to the pixel area PA. The color filters adjacent to each other may have different colors (or in some cases may be clear or white to pass therethrough a white light). In addition, the color filter CF may be overlapped with adjacent color filter CF in a boundary of the pixel area PA.

Although the display panel includes the color filter CF in the present example embodiment, the display panel may have various modifications. For example, when the liquid crystal layer LC includes blue phase liquid crystals or cholesteric liquid crystals, the color filter CF may be eliminated.

The sixth insulation layer 116 is disposed on the color filter CF to cover the color filter CF.

According to the example embodiment, the liquid crystal layer (or another appropriate and initially liquid form of optical control material) is introduced into the otherwise monolithically integrally formed structure by using the tunnel-shaped cavity as a passageway for flooding the tunnel-shaped and interconnected cavities of the various cells with the liquid form of the optical control material. Accordingly a unitary structure may be monolithically integrally formed and the number of separate substrates used for creating the display apparatus may be reduced.

In addition, texture in a peripheral area of the liquid crystal layer may be controlled by adjusting the angle of the cross section sidewalls of the liquid crystal layer.

In addition, the angle of the sidewalls of the liquid crystal layer may be controlled by adjusting an order of forming a sacrificial layer that defines the cavity as will be seen below.

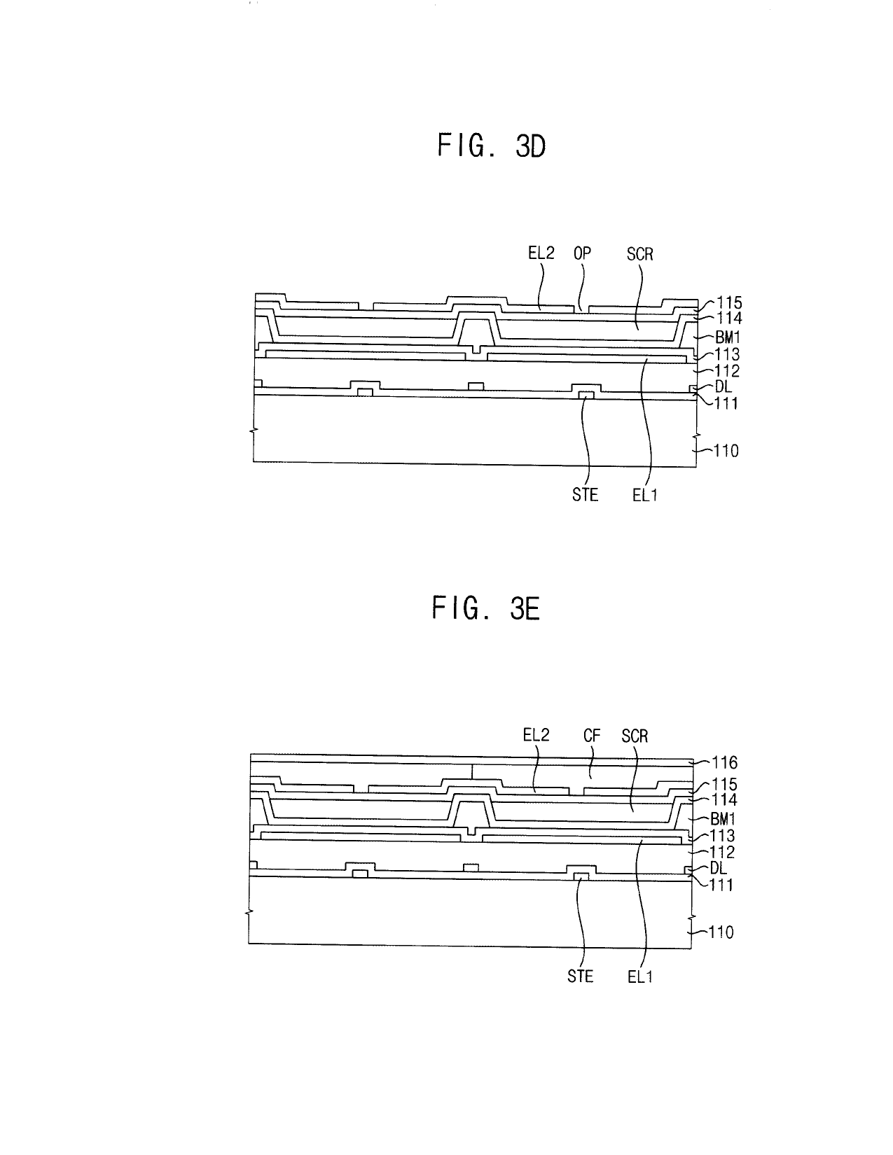

FIGS. 3A to 3F are cross-sectional views illustrating a method of manufacturing a display panel according to an example embodiment of the present disclosure of invention.

The display apparatus of the illustrated manufacturing method is substantially the same as the display apparatus of FIGS. 1 to 2C. Thus, any further detailed descriptions concerning the same elements will be omitted. In the FIGS. 3A to 3F, continuous set of immediately adjacent two pixels is illustrated corresponding to a cross-sectional view taken along line I-I′ of FIG. 1.

Referring FIG. 3A, a gate electrode (not shown, refer to GE of FIG. 2B), a storage electrode STE, a gate line (refer to GL of FIG. 2B) and a storage line (refer to SL of FIG. 1) are first monolithically integrally formed on a substrate 110. More specifically, a conductive layer is blanket formed on the substrate 110, and then the conductive layer is patterned to define the gate electrode (refer to GE of FIG. 2B), the storage electrode STE, the gate line (refer to GL of FIG. 2B) and the storage line (refer to SL of FIG. 1) via photolithography.

A first insulation layer 111 is formed on the substrate 110 on which the patterned gate electrode (refer to GE of FIG. 2B), the storage electrode STE, the gate line (refer to GL of FIG. 2B) and the storage line (refer to SL of FIG. 1) are already formed. The first insulation layer 111 covers and insulates the gate electrode (refer to GE of FIG. 2B), the storage electrode STE, the gate line (refer to GL of FIG. 2B) and the storage line (refer to SL of FIG. 1).

Referring to FIG. 3B, a semiconductor pattern (refer to SM of FIG. 2B) is formed on the first insulation layer 111. A data line DL, a source electrode (refer to SE of FIG. 2B) and a drain electrode (refer to DE of FIG. 2C) are formed on the first insulation layer 111 on which the semiconductor pattern (refer to SM of FIG. 2B) is formed.

A second insulation layer 112 is then formed on the first insulation layer 111 on which the semiconductor pattern (refer to SM of FIG. 2B), the data line DL, the source electrode (refer to SE of FIG. 2B) and the drain electrode (refer to DE of FIG. 2C) are already formed. The second insulation layer 112 covers and insulates a thin film transistor TFT (refer to TFT of FIG. 2B) and the data line DL.

A contact hole (refer to CH of FIG. 2) is formed (e.g., by etching) through the second insulation layer 112. The contact hole exposes a portion of the drain electrode DE.

A first electrode EL1 is formed on the second insulation layer 112. The first electrode EL1 may include a transparent conductive material, such as indium tin oxide (ITO) or indium zinc oxide (IZO). The first electrode EL1 is electrically connected to the drain electrode DE through the contact hole (refer to CH of FIG. 2).

A second black matrix BM2 may be formed between the second insulation layer 112 and a third insulation layer 113 to overlap with the thin film transistor TFT (refer to TFT of FIG. 2B).

The third insulation layer 113 is formed on the second insulation layer 112 on which the first electrode EL1 is formed. The third insulation layer 113 covers and insulates the first electrode EL1.

Referring to FIG. 3C, a first black matrix BM1 is formed on the third insulation layer 113 to have openings that define the illustrated, substantially trapezoidal cross sections thereof. A lower width of each trapezoidal cross section of the first black matrix BM1 may be formed to be greater than an upper width of the same. A sidewall of the trapezoidal cross section of the first black matrix BM1 and an under surface of the same which faces the third insulation layer 113 thus forms a predetermined acute angle. Thus, a lower width of the trapezoidal cross section of the first black matrix BM1 may be greater than an upper width of the first black matrix BM1.

A fourth insulation layer 114 is formed on the third insulation layer 113 on which the first black matrix BM1 is formed. The fourth insulation layer 114 includes an inorganic insulating material, such as a silicon nitride (SiNx) and/or a silicon oxide (SiOx).

Referring FIG. 3D, a sacrificial layer SCR is formed on the fourth insulation layer 114. The sacrificial layer SCR corresponds to the pixel area (refer to PA of FIG. 1). The sacrificial layer SCR extends in a second direction D2 (refer to D2 of FIG. 1). The sacrificial layer SCR may include an organic macromolecule material (e.g., a ploymerizable monomer), such as an organic material including benzocyclobutene (BCB) and acryl resin. The sacrificial layer SCR may be formed and planarized via an evaporation (e.g., PVD) process and a post-deposition ashing process or an evaporation and polishing (e.g., CMP) process. In addition, the sacrificial layer SCR may be formed via an inkjet deposition process or spin coating process, and is not limited to these merely exemplary methods.

The sacrificial layer SCR will be selectively removed later to form a tunnel-shaped cavity, so that the formed and later removed sacrificial layer SCR has dimensions that are essentially the same as the to-be-formed tunnel-shaped cavity.

A fifth insulation layer 115 is formed on the fourth insulation layer 114 on which the sacrificial layer SCR is formed. The fifth insulation layer 115 includes an inorganic insulating material, such as a silicon nitride (SiNx) and/or a silicon oxide (SiOx).

A second electrode EL2 is formed on the fifth insulation layer 115. The second electrode EL2 may include a transparent conductive material, such as indium tin oxide (ITO) or indium zinc oxide (IZO). The second electrode EL2 may have one or more openings OP to form a slit pattern. The slit pattern overlaps the storage electrode STE, whereby the storage electrode STE blocks light from passing through the openings OP and thus showing their presence by way of less than fully controlled liquid crystal regions. A conductive layer is blanket formed, and the conductive layer is patterned into the second electrode EL2 having the openings OP via photolithography.

Referring to FIG. 3E, A color filter CF is formed on the fifth insulation layer 115 on which the second electrode EL2 is formed.

The color filter CF is formed to correspond in position to the first and second electrodes, EL1 and EL2. Referring to FIG. 2, the color filter CF may not be formed on the thin film transistor TFT (refer to TFT of FIG. 2B). The color filter CF may include a red color filter, a green color filter and blue color filter. The color filter CF may include an organic macromolecule material (polymer). The color filter CF may be formed using a photosensitive macromolecule material via photolithography. The color filter CF may be formed via inkjet process and etc.

Although the color filters CF are not overlapped with each other at boundary of the pixel area in the present example embodiment, the color filters CF may have various modifications. For example, the color filters CF may be overlapped with each other at the boundary of the pixel area (refer to PA of FIG. 1). Each of the pixels includes its respectively colored color filter CF. The color filters adjacent to each other may have different colors

A sixth insulation layer 116 is formed on the color filter CF. A hole H (see FIG. 2C) is formed over the thin film transistor TFT (refer also to TFT of FIG. 2B). Thus, the hole H is formed through the fourth insulation layer 114, the fifth insulation layer 115, the second electrode EL2 and the sixth insulation layer 116. The hole H exposes a portion of the sacrificial layer SCR.

Although the method of manufacturing the display panel includes forming the third insulation layer 113 in the present example embodiment, forming the third insulation layer 113 is optional and may be eliminated. The sacrificial layer SCR may be isolated by the fourth insulation layer 114 and the fifth insulation layer 115, without the third insulation layer 113 being present.

Similarly, forming others of the insulation layers may be optionally eliminated. For example, the first electrode EL1 the second electrode EL2 and the first black matrix BM1 includes protectable material (protectable from selective removal) when the sacrificial layer SCR is selectively removed, then the third to sixth insulation layer 113, 114, 115 and 116 are unnecessary to be formed.

Referring to FIG. 3F, the tunnel-shaped cavity is formed by selectively removing the sacrificial layer SCR for example via a plasma process. The sacrificial layer SCR is accessed through the hole H and at least partially etched into via an anisotropic plasma etching process. Thereafter, a selective and anisotropic removal process is applied for selectively removing the material of the sacrificial layer SCR while essentially not removing the surrounding other materials. Accordingly, an under surface of the fifth insulation layer 115 and an upper surface of the fourth insulation layer 114 are exposed by way of the selective and anisotropic removal process. The under surface of the fifth insulation layer 115 and the upper surface of the fourth insulation layer 114 are inner surfaces of the tunnel-shaped cavity TSC.

The used plasma process is for anisotropically removing organic material. A microwave driven and oxygen (e.g., O2) producing plasma may be used but the process is not limited thereto. Stage temperature, chamber pressure, using gas of the microwave O2 plasma may be adjusted to selectively etch only organic insulating material. Accordingly, the fourth insulation layer 114 and the fifth insulation layer 115 including inorganic insulating material are not etched. In the microwave O2 plasma etching process, the stage temperature of an etching chamber may be about 100-300 Celsius degree, amount of O2 flow may be about 5000-10000 sccm, amount of diazene (N2H2) flow may be about 100-1000 sccm, pressure of the etching chamber may be about 2 Torr, and applied power supply may be about 100-4000 W.

Alternatively, an isotropic and selective wet solvent removal process may be used for removing the organic material of the sacrificial layer SCR.

After the tunnel-shaped cavity is formed, an alignment layer PI is formed on the interior surfaces of the tunnel-shaped cavity. Thus, the alignment layer PI is formed on the upper surface of the fourth insulation layer 114 and the under surface of the fifth insulation layer 115. The alignment layer PI may be formed using a hardenable alignment solution. The alignment solution may include a mixture of alignment material, such as polyamide, and proper solvent such as polyamide. The alignment solution is supplied in a liquid type, so that the alignment solution moves in the tunnel-shaped cavity due to capillary phenomenon and coats the interior surfaces of the tunnel-shaped cavity. The alignment solution may be supplied using inkjet with a micro pipette, or using vacuum injection equipment. After that, the solvent is selectively removed. The substrate 110 may be kept in dry room temperature or in a heated dry and/or low pressure environment to selectively remove the solvent.

The alignment layer PI may be eliminated according to type of the liquid crystal layer, or shapes of the first and second electrodes EL1 and EL2. For example, the first and second electrodes EL1 and EL2 have a specific pattern, then the alignment layer PI may be eliminated. The alignment orientation of the alignment layer PI may be established photonically as (and/or after) its solvent is removed. Alternatively, the alignment orientation of the alignment layer PI may be established after the liquid crystal material (LC) is next introduced where the alignment layer PI is photocured (further hardened) in the presence of an orientation defining electric field.

A liquid crystal layer LC including liquid crystal molecules is next introduced into the tunnel-shaped cavity in which the alignment layer coating PI has been formed. The liquid crystal molecules are supplied in a liquid type, so that the liquid crystal molecules move in the tunnel-shaped cavity due to capillary phenomenon. The liquid crystal layer LC may be supplied using inkjet with a micro pipette, or using vacuum injection equipment. Using the vacuum injection equipment, the whole is immersed into a container receiving the liquid crystal molecules, and then pressure of a chamber in which the container is disposed is decreased, then the liquid crystal molecules moves in the tunnel-shaped cavity due to capillary phenomenon.

A protecting layer 118 may be further formed on the sixth insulation layer 116 to cover and seal the hole H after the liquid crystal material (or optionally a different image controlling and electrically responsive material) is introduced.

The protecting layer 118 includes semi-hardening macromolecule material. The macromolecule material may have liquidity before hardening. The semi-hardening macromolecule material is formed having a flat shape, then the flat shaped semi-hardening macromolecule material is disposed on the display panel and pressed to form the protecting layer 118. The semi-hardening macromolecule material may be supplied to a recessed portion (e.g., the hole H) of the display panel due to the liquidity.

After the protecting layer 118 is formed, a first polarizing plate (not shown) under the substrate 110, and a second polarizing plate (not shown) on the protecting layer 118 may be attached to the unitary panel. Light is polarized by the first and second polarizing plates. Axis of the first polarizing plate may be substantially perpendicular to axis of the second polarizing plate.

The second polarizing plate may be attached on the protecting layer 118 by additional adhesive. When the protecting layer 118 includes adhesive macromolecule, the second polarizing plate may be directly attached to the protecting layer 118.

The second polarizing plate may be formed on the protecting layer 118, and not limited thereto. For example, adhesive macromolecule layer is formed on the second polarizing plate, and then the adhesive macromolecule layer of the second polarizing plate is disposed on the display panel and pressed, so that the protecting layer 118 and the second polarizing plate may be formed at the same time.

The first polarizing plate may be attached under the substrate 110 using adhesive.

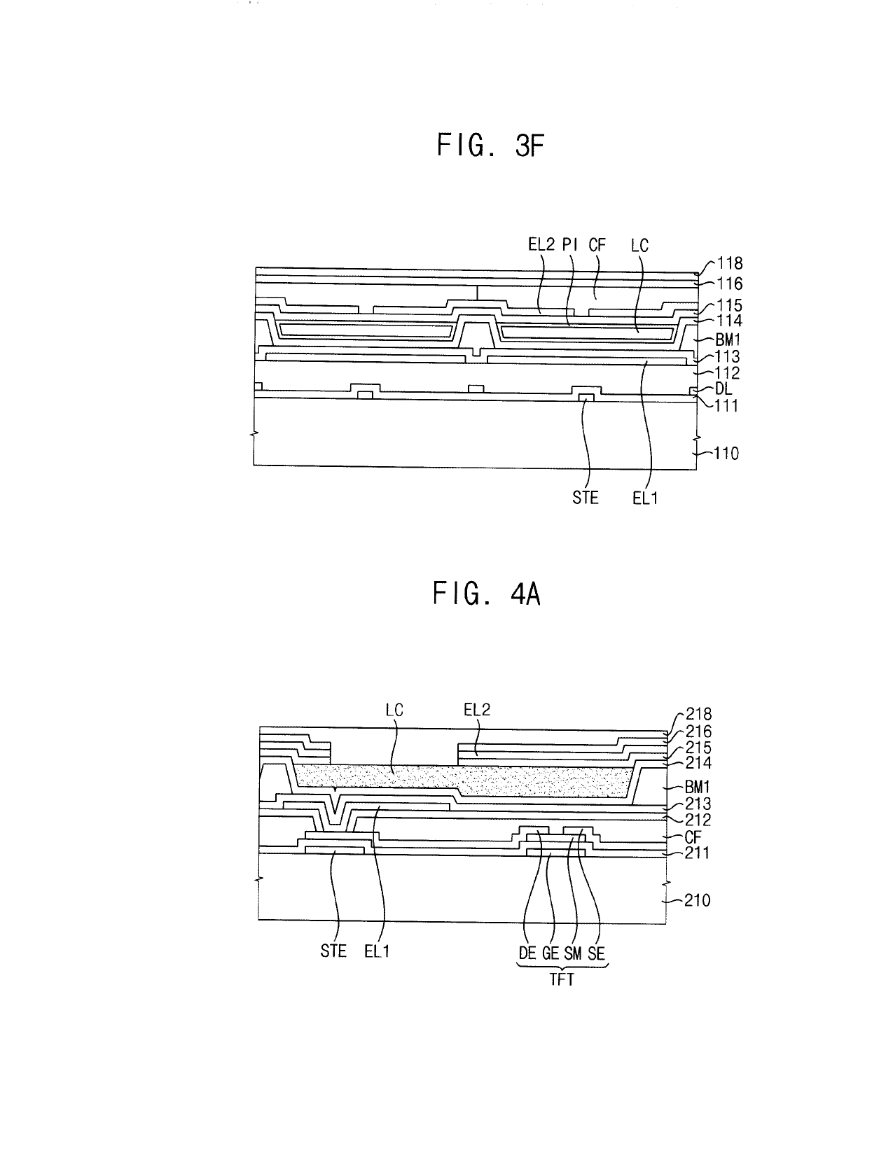

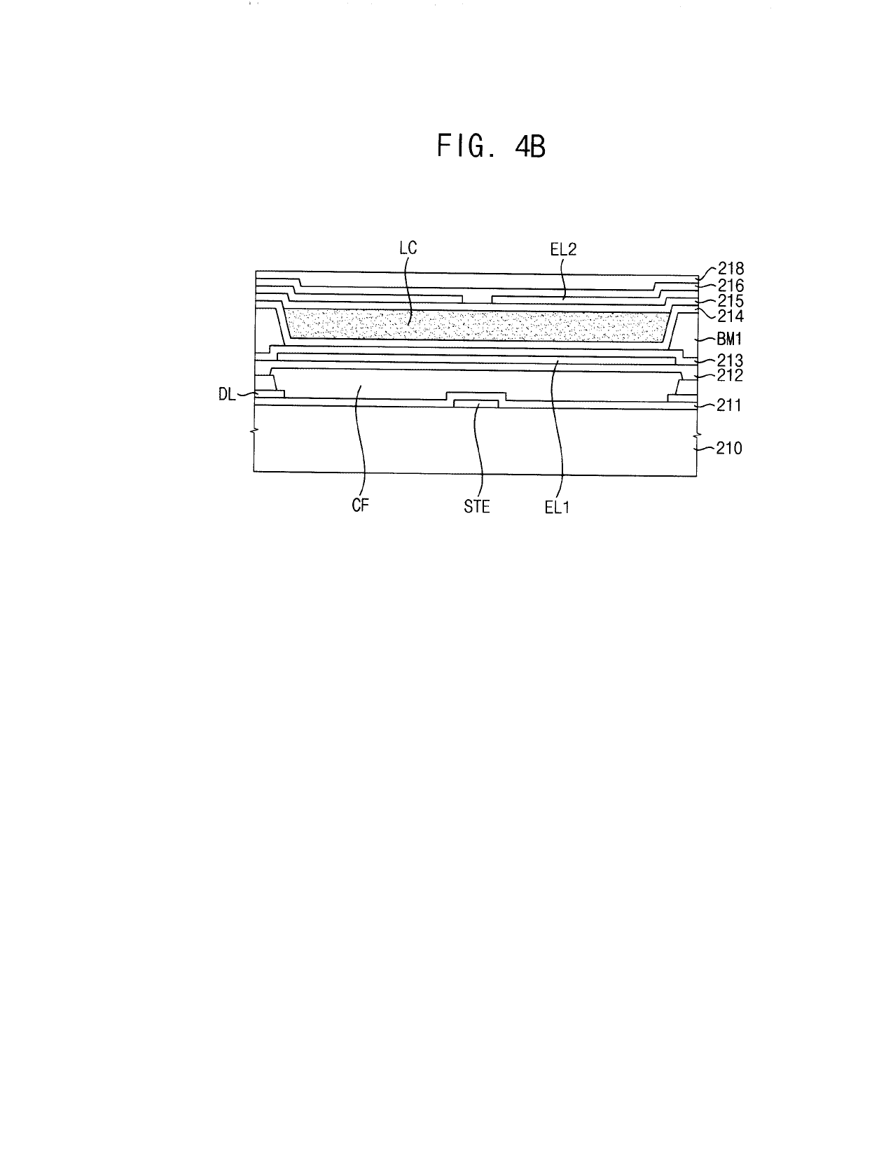

FIG. 4A is a cross-sectional view, which is correspond to the line I-I′ of FIG. 1, and shows a display apparatus according to another example embodiment. FIG. 4B is a cross-sectional view, which is correspond to the line II-II′ of FIG. 1, of the display apparatus of FIG. 4A.

Referring to FIGS. 4A and 4B, the display panel is substantially the same as the display panel of FIG. 1, except for a position of a color filter. The color filter is below the LC layer in this case. Thus, any further detailed descriptions concerning the same elements will be omitted.

The display panel includes a substrate 210, a thin film transistor TFT, a first electrode EL1, a second electrode EL2, a liquid crystal layer LC, a first black matrix BM1 and a color filter CF. The display panel further includes a first insulation layer 211, a second insulation layer 212, a third insulation layer 213, a fourth insulation layer 214, a fifth insulation layer 215, and a sixth insulation layer 216.

A gate electrode GE of the thin film transistor TFT is disposed on the substrate 210. A storage electrode STE is formed on the substrate 210.

The first insulation layer 211 is formed on the gate electrode GE of the thin film transistor TFT.

A semiconductive material pattern SM (could be formed of a semiconductive oxide or of a more traditional semiconductor material such as silicon) of the thin film transistor TFT overlaps with the gate electrode GE on the first insulation layer 211. A source electrode SE of the thin film transistor TFT is disposed on the semiconductor pattern SM, and connected to the data line DL. The drain electrode DE of the thin film transistor TFT is disposed on the semiconductor pattern SM and the first insulation layer 211.

The color filter CF is disposed on the thin film transistor TFT and the data line DL. The color filter CF supplies coloring to the light. The color filter CF may include a red color filter, a green color filter and blue color filter. The color filter CF corresponds to the pixel area PA. The color filters adjacent to each other may have different colors. In addition, the color filter CF may be overlapped with adjacent color filter CF in a boundary of the pixel area PA.

The second insulation layer 212is disposed on (above) the color filter CF.

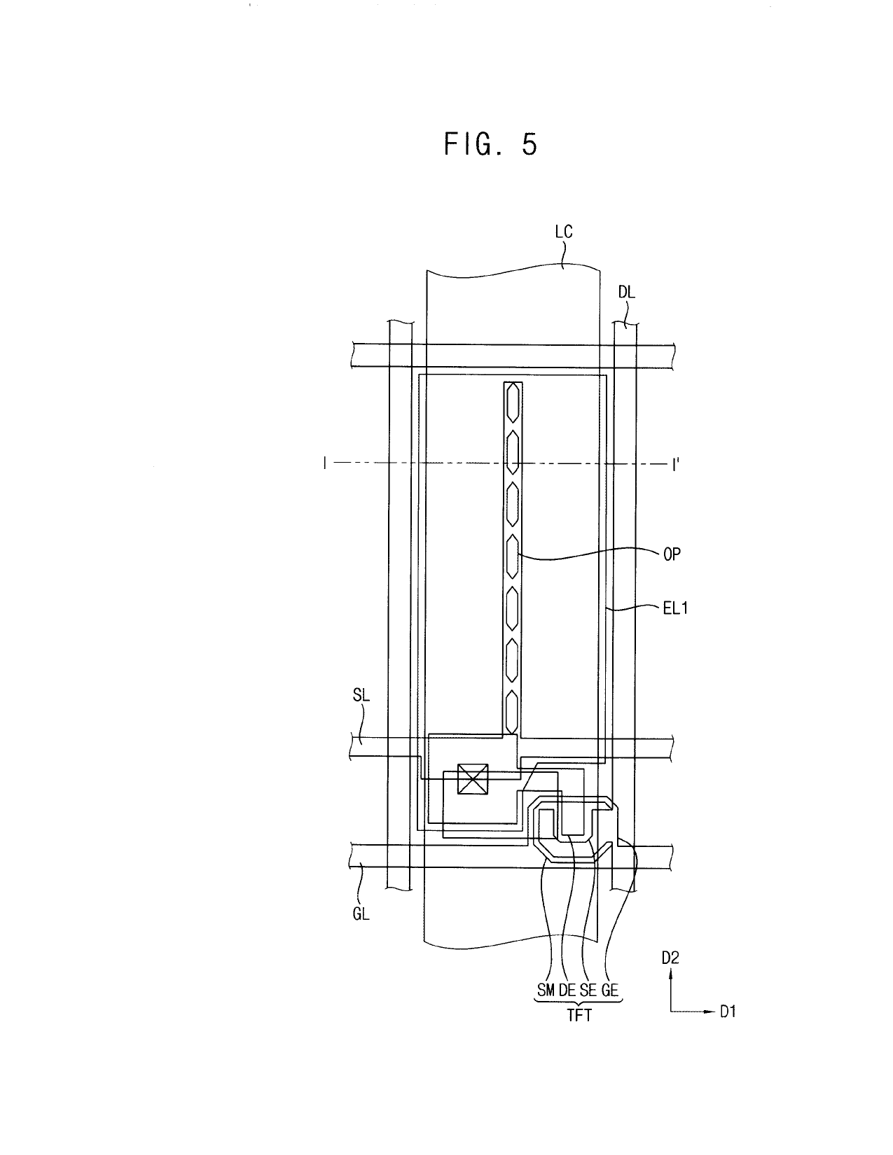

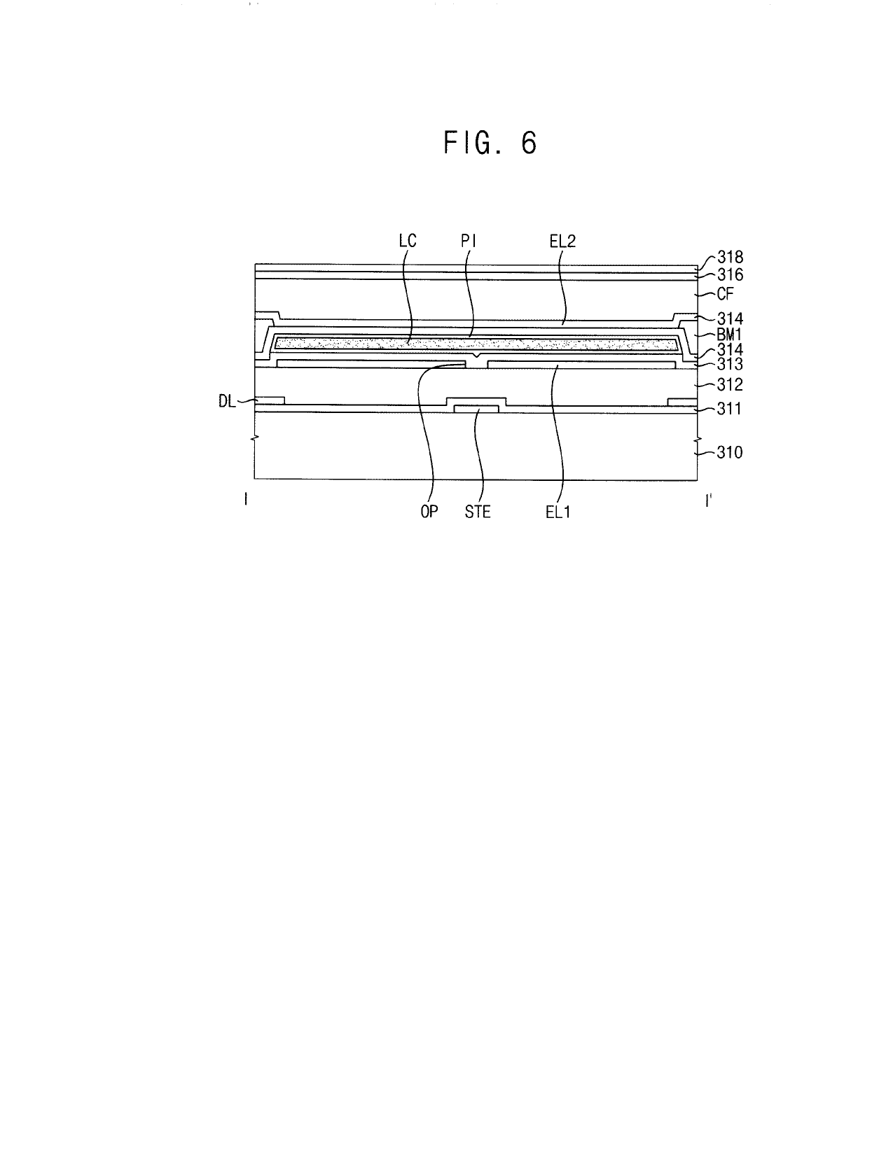

FIG. 5 is a plan view illustrating a display apparatus according to still another example embodiment. FIG. 6 is cross-sectional view taken along a line I-I′ of FIG. 5.

Referring to FIGS. 5 and 6, is substantially same as the display panel of FIG. 1, except for shape of a liquid crystal layer LC, of the first black matrix BM1 and the location of the domains establishing openings OP. Thus, any further detailed descriptions concerning the same elements will be omitted.

The display panel includes a substrate 310, a thin film transistor TFT, a first electrode EL1, a second electrode EL2, a liquid crystal layer LC and a first black matrix BM1. The display panel further includes a first insulation layer 311, a second insulation layer 312, a third insulation layer 313, a fourth insulation layer 314, a fifth insulation layer 315, a color filter CF, and a sixth insulation layer 316.

The first electrode EL1 may have the openings OP defined therein to thus form a slit pattern.

The third insulation layer 313 is disposed on the first electrode EL1 The liquid crystal layer LC is disposed on the third insulation layer 313. An upper width of the liquid crystal layer LC is greater than a lower width of the liquid crystal layer LC (this being due to the inverted trapezoid shapes of the BM1 cross section).

The fourth insulation layer 314 is disposed on the liquid crystal layer LC. The first black matrix BM1 is disposed on the fourth insulation layer 314, and overlaps with the data line DL. The first black matrix BM1 compartmentalizes the liquid crystal layer LC. In this embodiment, an upper width of the substantially trapezoidal shape of the cross sections of the first black matrix BM1 is greater than a lower width of the same.

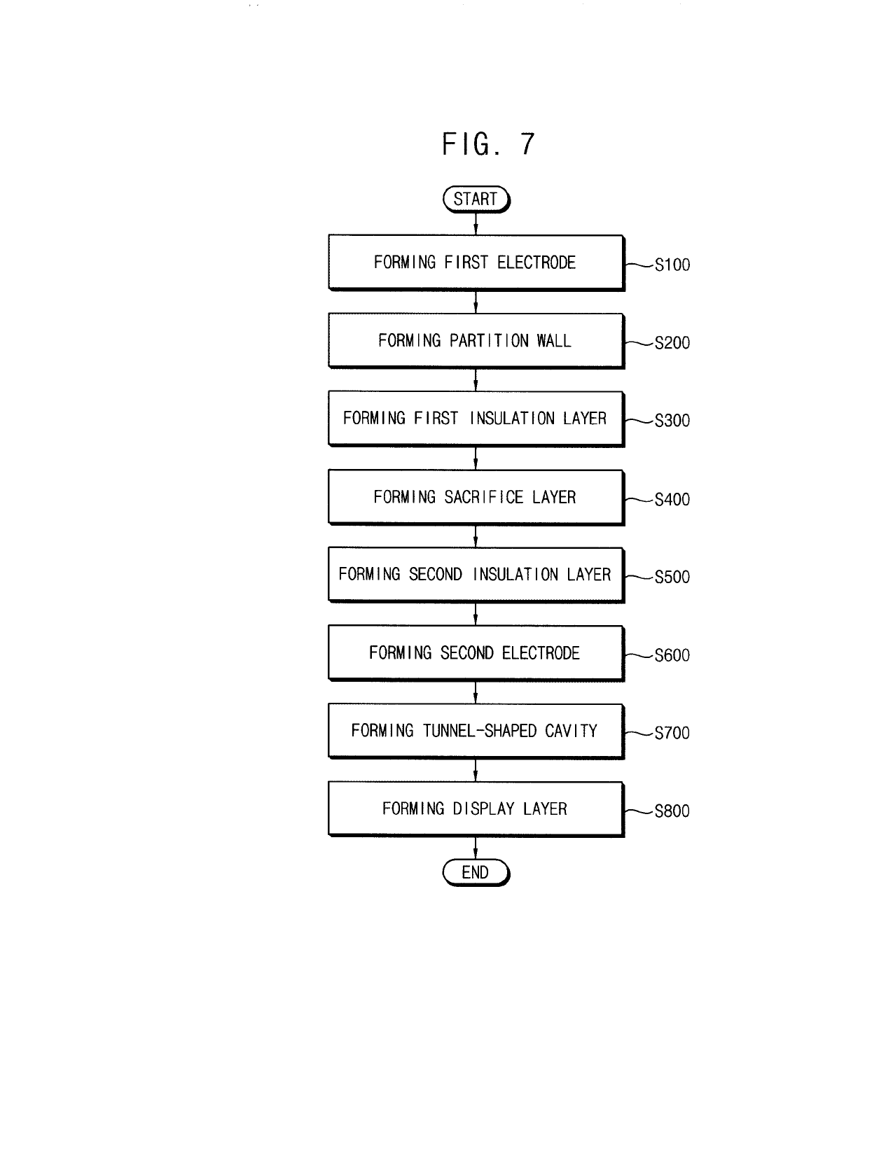

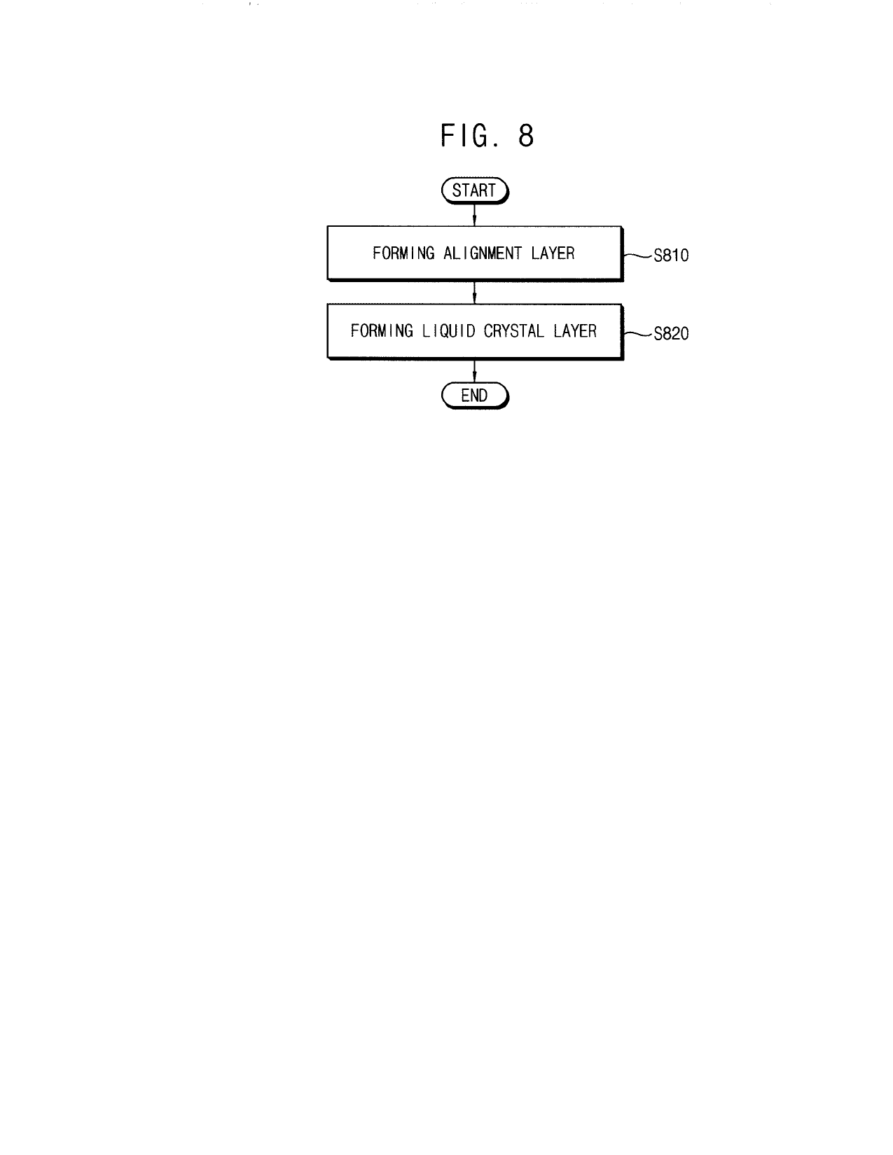

FIG. 7 is a flowchart illustrating a method of manufacturing a display panel according to an example embodiment of the present disclosure of invention. FIG. 8 is a flowchart illustrating forming liquid crystal layer of FIG. 7.

Referring to FIG. 7, the method of manufacturing the display panel include forming a first electrode S100, forming a partition wall S200, forming a first insulation layer (refer to fourth insulation layer 114 of FIG. 2A) S300, forming a sacrificial layer S400, forming a second insulation layer (refer to fifth insulation layer 115 of FIG. 2A) S500, forming a second electrode S600, forming a tunnel-shaped cavity S700, and forming a display layer S800. Forming the display layer S800 includes forming an alignment layer S810, and forming a liquid crystal layer S820 (or introducing into the pre-formed tunnel cavity another electrically responsive and optic attribute changing material). The display panel according to the present example embodiment is substantially same as the display panel of FIG. 1. Thus, any further detailed descriptions concerning the same elements will be omitted.

In a step of forming the first electrode S100, the first electrode is monolithically integrally formed on a substrate.

In a step of forming the partition wall S200, the partition wall overlapping with both ends of the first electrode in a first direction in a plan view is formed.

In a step of forming the first insulation layer (refer to fourth insulation layer 114 of FIG. 2A) S300, the first insulation layer is formed on the first electrode on which the partition wall is formed.

In a step of forming the sacrificial layer S400, the sacrificial layer is formed on the first insulation layer.

In a step of forming the second insulation layer (refer to fifth insulation layer 115 of FIG. 2A) S500, the second insulation layer is formed on the sacrificial layer and the first insulation layer.

In a step of forming the second electrode S600, the second electrode is formed on the second insulation layer.

The first and second insulation layer may include inorganic insulating material.

In a step of forming the tunnel-shaped cavity S700, the sacrificial layer is selectively removed (sacrificed) to thereby leave behind the tunnel-shaped cavity between the first and second electrodes. A hole through the second electrode may be formed to remove the material of the sacrificial layer. The sacrificial layer may include organic macromolecule material, and may be selectively removed using a microwave O2 plasma process and/or any other appropriate and selective removal process.

In a step of forming the display layer 5800, the display layer is formed in the tunnel-shaped cavity. An upper width of the display layer may be greater than a lower width of the display layer. In a step of forming the alignment layer S810, the alignment layer is formed in (e.g., coated onto the interior surfaces of) the tunnel-shaped cavity. In a step of forming the liquid crystal layer S820, the liquid crystal layer is formed in the tunnel-shaped cavity in which the alignment layer is formed by injecting liquid crystal molecules into the tunnel-shaped cavity. As mentioned, it is within the contemplation of the present disclosure that other electrically responsive and optic attribute changing materials (e.g., electrophoretic material) may be flowed into the tunnel-shaped cavity in initially liquid form and then optionally modified thereafter as may be necessary.

According to the example embodiments, adjusting forming order of the sacrificial layer and the first black matrix (partition wall), the angle of the sidewall of the liquid crystal layer may be controlled, so that display quality in a boundary of pixel may be improved.

The foregoing is illustrative of the present teachings and is not to be construed as limiting thereof. Although a few example embodiments have been described, those skilled in the art will readily appreciate in view of the foregoing that many modifications are possible in the example embodiments without materially departing from the novel teachings and advantages disclosed here. Accordingly, all such modifications are intended to be included within the scope of the present teachings. In the claims, means-plus-function clauses are intended to cover the structures described herein as performing the recited function and not only structural equivalents but also functionally equivalent structures. Therefore, it is to be understood that the foregoing is illustrative of the present disclosure of invention and is not to be construed as limited to the specific example embodiments disclosed, and that modifications to the disclosed example embodiments, as well as other example embodiments, are intended to be included within the scope of the teachings.

What is claimed is:

1. A display panel comprising:
a substrate;
a first electrode disposed on the substrate;
a partitioning member disposed on the substrate on which the first electrode is disposed, and defining a substantially containerizing-volume above the first electrode;
a variable light attribute controlling material disposed in the containerizing volume defined by the partitioning member, an upper dimension of the light attribute controlling material being greater than a corresponding lower dimension of the attribute controlling material; and
a second electrode disposed above the partitioning member and above the light attribute controlling material, and insulated from the first electrode.

2. The display panel of claim 1, further comprising a first insulation layer disposed between the first electrode and the light attribute controlling material.

3. The display panel of claim 2, further comprising a second insulation layer disposed between the light attribute controlling material and the second electrode.

4. The display panel of claim 3, wherein the first and second insulation layers respectively comprise respective inorganic insulating materials.

5. The display panel of claim 3, further comprising a third insulation layer disposed between the first insulation layer and the first electrode, and disposed under the partitioning member.

6. The display panel of claim 1, further comprising:
a thin film transistor disposed on the substrate and comprising a gate electrode, a source electrode and a drain electrode; and
a storage electrode forming a capacitor with the drain electrode.

7. The display panel of claim 6, wherein the partitioning member includes a black matrix disposed above the thin film transistor and configured to block leakage light that is not substantially controllable by the light attribute controlling material.

8. The display panel of claim 6, wherein the storage electrode comprises a storage electrode branch forming a capacitor with the first electrode.

9. The display panel of claim 8, wherein the second electrode has one or more openings overlapping with the storage electrode branch and subdividing the second electrode into two or more domains.

10. The display panel of claim 8, wherein the first electrode has orientation openings overlapping with the storage electrode branch and subdividing the first electrode into two or more domains.

11. The display panel of claim 1, wherein an upper width of the partitioning member is smaller than a lower width of the partitioning member.

12. The display panel of claim 1, further comprising a color filter disposed on the second electrode.

13. The display panel of claim 12, further comprising:
a fourth insulation layer disposed on the color filter; and
a protecting layer disposed on the fourth insulation layer.

14. The display panel of claim 1, further comprising an alignment layer surrounding the light attribute controlling material.

15. A method of forming a display panel, comprising:
forming a first electrode on a substrate;
forming a partitioning member that defines a substantially containerizing volume above the first electrode, the containerizing volume of the partitioning member having at least one slanted sidewall in an interior of the volume, where the containerizing volume overlaps the first electrode;
forming a sacrificial member in and essentially filling the substantially containerizing volume;
forming a second electrode on the sacrificial layer;
defining a tunnel-shaped cavity by selectively removing the sacrificial member from the interior of the containerizing volume, the tunnel-shaped cavity thereby being disposed between the first electrode and the second electrode; and
forming a light attribute controlling material in the tunnel-shaped cavity.

16. The method of claim 15, further comprising:
forming a lower insulation layer on the first electrode and on the partitioning member, where the lower insulation layer is formed before forming the sacrificial layer and thus the lower insulation layer is disposed under the sacrificial layer; and
forming an upper insulation layer above the sacrificial layer before forming the second electrode.

17. The method of claim 15, wherein the sacrificial layer comprises an organic material, and the sacrificial layer is selectively removable for example by using microwave O2 plasma process.

18. The method of claim 15, wherein forming the light attribute controlling material includes causing an upper width of the light attribute controlling material to be wider than a lower width of the light attribute controlling material.

19. The method of claim 15, wherein forming the tunnel-shaped cavity comprises forming a hole through the second electrode to access the sacrificial layer and to thereby subject the sacrificial layer to a selective removal process.

20. The method of claim 15, wherein forming the light attribute controlling material comprises:
forming an alignment layer on one or more interior surfaces of the tunnel-shaped cavity; and
flowing the light attribute controlling material or a liquid precursor thereof into the tunnel-shaped cavity in which the alignment layer is already formed.

21. A display panel, comprising:
a substrate;
a first electrode disposed on the substrate;
a partitioning member disposed on the substrate on which the first electrode is disposed, and having an opening;
a light attribute controlling material disposed in the opening of the partitioning member, where an upper width of the light attribute controlling material is smaller than a lower width of the light attribute controlling material;
a second electrode disposed above the partitioning member and above the light attribute controlling material, the second electrode being insulated from the first electrode;
a thin film transistor disposed on the substrate and comprising a gate electrode, a source electrode and a drain electrode; and
a storage electrode forming a capacitor with the drain electrode and having a storage electrode branch forming a capacitor with the first electrode,
wherein the partitioning member has a wall section with a non-rectangular cross section and an upper width of the non-rectangular cross section is substantially different than an opposed lower width of the non-rectangular cross section, and
wherein at least one of the first and second electrodes has an opening overlapping with the storage electrode branch.
